(19) United States
(12) Patent Application Publication
(10) Pub. No.: US 2022/0168864 A1
(43) Pub. Date: Jun. 2, 2022

(54) POLISHING RECIPE DETERMINATION DEVICE

(71) Applicant: EBARA CORPORATION, Tokyo (JP)

(72) Inventors: Yoshikazu Kato, Tokyo (JP); Makoto Fukushima, Tokyo (JP); Keisuke Namiki, Tokyo (JP); Shingo Togashi, Tokyo (JP)

(21) Appl. No.: 17/419,029

(22) PCT Filed: Oct. 16, 2019
(86) PCT No.: PCT/JP2019/040596

§ 371 Date: Feb. 7, 2022

(30) Foreign Application Priority Data
Dec. 28, 2018 (JP) 2018-246913

(51) Int. Cl. B24B 37/005; G06N 20/20; G06K 9/62

(52) U.S. Cl. CPC B24B 37/005; H01L 21/02013; G06K 9/6264; G06N 20/20

(57) ABSTRACT

An information processing apparatus is an information processing apparatus that determines a polishing recipe based on area response data acquired by changing a pressure for each area in a polishing head, the apparatus including an irregularity-presence-or-absence estimation unit that estimates and outputs whether an irregularity is present using new area response data as an input, a screening unit estimates and outputs, when the irregularity-presence-or-absence estimation unit estimates that an irregularity is present, area response data after the removal of the irregularity using area response data estimated that an irregularity is present as an input, and a simulation unit that determines a polishing recipe by simulation based on area response data estimated by the irregularity-presence-or-absence estimation unit that no irregularity is present or a response for each area after the removal of the irregularity estimated by the screening unit.

### TECHNICAL FIELD

The present disclosure relates to a polishing recipe determination device.

### BACKGROUND ART

In recent years, with progress in higher integration of semiconductor devices, the interconnections of circuits are downscaled, and the distance between interconnections are becoming narrower. In the manufacture of semiconductor devices, a large number of types of materials are repeatedly formed in a film shape on a silicon wafer to form a stacked structure. In order to form this stacked structure, a technique of planarizing the surface of a wafer is important. As one of such schemes of planarizing the surface of a wafer, a polishing apparatus (also referred to as a chemical-mechanical polishing apparatus), which performs chemical-mechanical polishing (CMP), is widely used.

This type of polishing apparatus generally includes a polishing table to which a polishing pad is attached, a top ring (also referred to as a polishing head) that holds a wafer, and a nozzle that supplies a polishing liquid onto the polishing pad. The wafer is pressed against the polishing pad using the top ring while the polishing liquid is supplied onto the polishing pad from the nozzle for relative displacement between the top ring and the polishing table, and thus the wafer is polished to planarize the surface.

In such a polishing apparatus, in the case in which the relative pressing force between the wafer and the polishing pad during polishing is not uniform over the entire surface of the wear, insufficient polishing or overpolishing occurs due to the pressing force applied to each portion of the wafer. In order to uniformize the pressing force to the wafer, a plurality of pressure chambers formed of an elastic film (membrane) is provided in a lower part of the top ring, and a fluid such as pressurized air is supplied to the plurality of pressure chambers individually, and thus the wafer is pressed against the polishing pad using a fluid pressure through the elastic film for polishing.

Area response data is acquired by a pressure variation experiment in which a test wafer is polished by changing a pressure for each pressure chamber (area) in the top ring, and a polishing recipe is determined by simulation based on the acquired area response data (e.g., see JP 2014-513434 A).

### SUMMARY OF INVENTION

### Technical Problem

The determination of the polishing recipe is performed by the skilled engineer, and thus the determination of a highly accurate polishing recipe is enabled for a short time (e.g., excellent in-plane uniformity). This is because a skilled engineer takes into consideration of past area response data or other processes on the area response data acquired by the pressure swing experiment, performs screening such as the complementation and removal of data, as necessary, and determines a polishing recipe based on area response data (with less noise) after screening.

Therefore, when an enormous amount of pieces of area response data acquired in the past can be learned, there is a possibility that the determination of a polishing recipe is further highly accurately improved. However, in practice, since the number of pieces of past area response data that can be learned by one engineer is limited, it is difficult to achieve further accuracy by conventional methods for determining a polishing recipe relying on the experience and knowledge of the engineer.

When the determination by the engineer can be replaced with a program of a computer, there is a possibility that the determination of the polishing recipe can be speeded up (made efficient). However, in practice, since sites at which an irregular value is produced or the size of the irregular value are not consistent in area response data, the engineer has to make determination at the sight of a graph each time, and it is not possible that the determination by the engineer is replaced with a conventional program that uses the conditional branch whether to satisfy predetermined conditions.

It is desired to provide a polishing recipe determination device that can achieve a highly accurate, efficient determination of a polishing recipe.

### Solution to Problem

A polishing recipe determination device according to an aspect of the present disclosure is

a polishing recipe determination device determining a polishing recipe based on area response data acquired by changing a pressure for each area in a top ring, the device including:

an irregularity-presence-or-absence estimation unit having a first learned model machine-learning relationship between past area response data and whether an irregularity is present in the past area response data, the irregularity-presence-or-absence estimation unit being configured to estimate and output presence or absence of an irregularity using new area response data as an input;

a screening unit having a second learned model machine-learning relationship between the past area response data with an irregularity and area response data after removal of an irregularity, the screening unit being configured to, when the irregularity-presence-or-absence estimation unit estimates that an irregularity is present, estimate area response data after the removal of the irregularity using an input of area response data estimated that an irregularity is present; and

a simulation unit configured to determine a polishing recipe by simulation based on area response data estimated that no irregularity is present by the irregularity-presence-or-absence estimation unit, or area response data after the removal of the irregularity estimated by the screening unit.

A polishing recipe determination device according to an aspect of the present disclosure is

a polishing recipe determination device determining a polishing recipe based on area response data acquired by changing a pressure for each area in a top ring, the device further including:

a simulation unit configured to determine a polishing recipe by simulation based on new area response data;

an acceptance evaluation unit configured to compare an actual polishing result obtained by actually polishing using the polishing recipe with a simulation polishing result obtained by simulation using the polishing recipe to evaluate an acceptance of the actual polishing result; and

a response data correction unit having a third learned model machine-learning relationship between a past actual polishing result, a simulation polishing result, area response data used for determination of a polishing recipe at that time, and corrected area response data, the response data correction unit being configured to, when the acceptance evaluation unit evaluates non-acceptance, estimate and output corrected area response data using an actual polishing result evaluated as non-acceptance, a simulation polishing result, and area response data used for determination of a polishing recipe at that time as an input, wherein

the simulation unit again determines a polishing recipe by simulation based on corrected area response data estimated by the response data correction unit.

A polishing recipe determination method according to an aspect of the present disclosure is

a polishing recipe determination method for determining a polishing recipe based on area response data acquired by changing a pressure for each area in a top ring, the response data being data that in regard to positions on a wafer, a variation in a polishing removal rate is divided by a variation in an air bag pressure, the method comprising the steps of:

estimating and outputting presence or absence of an irregularity by an irregularity-presence-or-absence estimation unit having a first learned model machine-learning relationship between past area response data and whether an irregularity is present in the past area response data using new area response data as an input;

estimating and outputting, when the irregularity-presence-or-absence estimation unit estimates that an irregularity is present, area response data after removal of the irregularity by a screening unit having a second learned model machine-learning relationship between past area response data with an irregularity and area response data after removal of an irregularity using area response data estimated that an irregularity is present as an input; and

determining a polishing recipe by simulation by the simulation unit based on area response data estimated that no irregularity is present by the irregularity-presence-or-absence estimation unit, or area response data after the removal of the irregularity estimated by a screening unit.

A polishing recipe determination method according to an aspect of the present disclosure is

a polishing recipe determination method for determining a polishing recipe based on area response data acquired by changing a pressure for each area in a top ring, the method comprising the steps of:

determining a polishing recipe by simulation by a simulation unit based on new area response data;

comparing an actual polishing result obtained by actually polishing using the polishing recipe with a simulation polishing result obtained by simulation using the polishing recipe by an acceptance evaluation unit to evaluate an acceptance of the actual polishing result;

estimating and outputting, when the acceptance evaluation unit evaluates non-acceptance, corrected area response data by a response data correction unit having a third learned model machine-learning relationship between a past actual polishing result, a simulation polishing result, area response data used for determination of a polishing recipe at that time, and corrected area response data using an actual polishing result evaluated as non-acceptance, the simulation polishing result, and area response E data used for determination of a polishing recipe at that time as an input; and

again determining a polishing recipe by simulation by the simulation unit based on the corrected area response data estimated by the response data correction unit.

A polishing recipe determination program according to an aspect of the present disclosure is

a polishing recipe determination program causing a computer to execute a process for determining a polishing recipe based on area response data acquired by changing a pressure for each area in a top ring, the program causing the computer to execute the steps of:

estimating and outputting presence or absence of an irregularity by an irregularity-presence-or-absence estimation unit having a first learned model machine-learning relationship between past area response data and whether an irregularity is present in the past area response data using new area response data as an input;

estimating and outputting, when the irregularity-presence-or-absence estimation unit estimates that an irregularity is present, area response data after removal of the irregularity by a screening unit having a second learned model machine-learning relationship between past area response data with an irregularity and area response data after removal of an irregularity using area response data estimated that an irregularity is present as an input; and

determining a polishing recipe by simulation by the simulation unit based on area response data estimated that no irregularity is present by the irregularity-presence-or-absence estimation unit, or area response data after the removal of the irregularity estimated by a screening unit.

A polishing recipe determination program according to an aspect of the present disclosure is

a polishing recipe determination program causing a computer to execute a process for determining a polishing recipe based on area response data acquired by changing a pressure for each area in a top ring, the response data being data that in regard to positions on a wafer, a variation in a polishing removal rate is divided by a variation in an air bag pressure, the program causing the computer to execute the steps of:

determining a polishing recipe by simulation by a simulation unit based on new area response data;

comparing an actual polishing result obtained by actually polishing using the polishing recipe with a simulation polishing result obtained by simulation using the polishing recipe by an acceptance evaluation unit to evaluate an acceptance of the actual polishing result;

estimating and outputting, when the acceptance evaluation unit evaluates non-acceptance, corrected area response data by a response data correction unit having a third learned model machine-learning relationship between a past actual polishing result, a simulation polishing result, area response data used for determination of a polishing recipe at that time, and corrected area response data using an actual polishing result evaluated as non-acceptance, a simulation polishing result, and area response data used for the determination of a polishing recipe at that time as an input; and

again determining a polishing recipe by simulation by the simulation unit based on the corrected area response data estimated by the response data correction unit.

A computer-readable recording medium according to an aspect of the present disclosure is

a computer-readable recording medium recording, in a non-transitory manner, a program causing a computer to execute a process for determining a polishing recipe based on area response data acquired by changing a pressure for each area in a top ring, the program causing the computer to execute the steps of:

estimating and outputting presence or absence of an irregularity by an irregularity-presence-or-absence estimation unit having a first learned model machine-learning relationship between past area response data and whether an irregularity is present in the past area response data using new area response data as an input;

estimating and outputting, when the irregularity-presence-or-absence estimation unit estimates that an irregularity is present, area response data after removal of the irregularity by a screening unit having a second learned model machine-learning relationship between past area response data with an irregularity and area response data after removal of an irregularity using area response data estimated that an irregularity is present as an input; and

determining a polishing recipe by simulation by the simulation unit based on area response data estimated that no irregularity is present by the irregularity-presence-or-absence estimation unit, or area response data after the removal of the irregularity estimated by a screening unit.

A computer-readable recording medium according to an aspect of the present disclosure is

a computer-readable recording medium recording, in a non-transitory manner, a program causing a computer to execute a process for determining a polishing recipe based on area response data acquired by changing a pressure for each area in a top ring, the program causing the computer to execute the steps of:

determining a polishing recipe by simulation by a simulation unit based on new area response data;

comparing an actual polishing result obtained by actually polishing using the polishing recipe with a simulation polishing result obtained by simulation using the polishing recipe by an acceptance evaluation unit to evaluate an acceptance of the actual polishing result;

estimating and outputting, when the acceptance evaluation unit evaluates non-acceptance, corrected area response data by a response data correction unit having a third learned model machine-learning relationship between a past actual polishing result, a simulation polishing result, area response data used for determination of a polishing recipe at that time, and corrected area response data using an actual polishing result evaluated as non-acceptance, a simulation polishing result, and area response data used for the determination of a polishing recipe at that time as an input; and

again determining a polishing recipe by simulation by the simulation unit based on the corrected area response data estimated by the response data correction unit.

### BRIEF DESCRIPTION OF DRAWINGS

FIG. 1 is a schematic diagram that illustrates the configuration of an information processing system according to an embodiment.

FIG. 2 is a schematic diagram that illustrates the configuration of a polishing apparatus according to an embodiment.

FIG. 3 is a schematic cross sectional view that illustrates the internal configuration of a top ring according to an embodiment.

FIG. 4 is a schematic cross sectional view that illustrates the internal configuration of a polishing table according to an embodiment.

FIG. 5 is a block diagram that illustrates the configuration of a polishing recipe determination device according to an embodiment.

FIG. 6 is a flowchart that illustrates an example of a polishing recipe determination method according to an embodiment.

FIG. 7 is a diagram that illustrates an example of a normal response amount profile on a center area.

FIG. 8A is a diagram that illustrates an example of a response amount profile on a center area having an irregularity at an asymmetric irregular point.

FIG. 8B is a diagram that illustrates an example of a response amount profile on a center area having an irregularity at an edge irregular point at the time of a pressure center swing.

FIG. 8C is a diagram that illustrates an example of a response amount profile on a center area having an irregularity at a polar irregular point.

FIG. 9 is a diagram that illustrates a remaining film profile in actual polishing and a remaining film profile in simulation in comparison.

FIG. 10 is a diagram that illustrates a response amount profile before correction and a response amount profile after correction in comparison.

### DESCRIPTION OF EMBODIMENTS

A polishing recipe determination device according to a first aspect of an embodiment is

a polishing recipe determination device determining a polishing recipe based on area response data acquired by changing a pressure for each area in a top ring, the device including:

an irregularity-presence-or-absence estimation unit having a first learned model machine-learning relationship between past area response data and whether an irregularity is present in the past area response data, the irregularity-presence-or-absence estimation unit being configured to estimate and output presence or absence of an irregularity using new area response data as an input;

a screening unit having a second learned model machine-learning relationship between the past area response data with an irregularity and area response data after removal of an irregularity, the screening unit being configured to, when the irregularity-presence-or-absence estimation unit estimates that an irregularity is present, estimate area response data after the removal of the irregularity using an input of area response data estimated that an irregularity is present; and

a simulation unit configured to determine a polishing recipe by simulation based on area response data estimated that no irregularity is present by the irregularity-presence-or-absence estimation unit, or area response data after the removal of the irregularity estimated by the screening unit.

According to such an aspect, since the irregularity-presence-or-absence estimation unit has a first learned model machine-learning the relationship between past area response data and the presence or absence of an irregularity, whether an irregularity is present in new area response data can be estimated for a short time, and highly accurate estimation is enabled corresponding to the amount of learning. Since the screening unit has a second learned model machine-learning relationship between past area response data with an irregularity and area response data after removal of an irregularity, area response data after the removal of the irregularity can be estimated from area response data estimated that an irregularity is present for a short time, and highly accurate estimation is enabled corresponding to the amount of learning. The simulation unit determines a polishing recipe by simulation based on area response data (with less noise) after screening, and thus a polishing recipe can be highly accurately and efficiently determined.

A polishing recipe determination device according to a second aspect of an embodiment is

a polishing recipe determination device according to the first aspect including:

an acceptance evaluation unit configured to compare an actual polishing result obtained by actually polishing using the polishing recipe with a simulation polishing result obtained by simulation using the polishing recipe to evaluate an acceptance of the actual polishing result; and

a response data correction unit having a third learned model machine-learning relationship between a past actual polishing result, a simulation polishing result, area response data used for determination of a polishing recipe at that time, and corrected area response data, the response data correction unit being configured to, when the acceptance evaluation unit evaluates non-acceptance, estimate and output corrected area response data using an actual polishing result evaluated as non-acceptance, a simulation polishing result, and area response data used for determination of a polishing recipe at that time as an input, in which

the simulation unit again determines a polishing recipe by simulation based on corrected area response data estimated by the response data correction unit.

According to such an aspect, since the response data correction unit has a third learned model machine-learning the relationship between a past actual polishing result, a simulation polishing result, area response data used for determination of a polishing recipe at that time, and corrected area response data, corrected area response data can be estimated from an actual polishing result evaluated as non-acceptance and the simulation polishing result and the area response data used for the determination of a polishing recipe at that time for a short time, and highly accurate estimation is enabled corresponding to the amount of learning. The simulation unit again determines a polishing recipe by simulation based on corrected area response data estimated by the response data correction unit, and thus a much highly accurate determination of the polishing recipe can be achieved.

A polishing recipe determination device according to a third aspect of an embodiment is

a polishing recipe determination device determining a polishing recipe based on area response data acquired by changing a pressure for each area in a top ring, the device including:

a simulation unit configured to determine a polishing recipe by simulation based on new area response data;

an acceptance evaluation unit configured to compare an actual polishing result obtained by actually polishing using the polishing recipe with a simulation polishing result obtained by simulation using the polishing recipe to evaluate an acceptance of the actual polishing result; and

a response data correction unit having a third learned model machine-learning relationship between a past actual polishing result, a simulation polishing result, area response data used for determination of a polishing recipe at that time, and corrected area response data, the response data correction unit being configured to, when the acceptance evaluation unit evaluates non-acceptance, estimate and output corrected area response data using an actual polishing result evaluated as non-acceptance, a simulation polishing result, and area response data used for determination of a polishing recipe at that time as an input, in which

the simulation unit again determines a polishing recipe by simulation based on corrected area response data estimated by the response data correction unit.

According to such an aspect, since the response data correction unit has a third learned model machine-learning the relationship between a past actual polishing result, a simulation polishing result, area response data used for determination of a polishing recipe at that time, and corrected area response data, corrected area response data can be estimated from an actual polishing result evaluated as non-acceptance and the simulation polishing result and the area response data used for the determination of a polishing recipe at that time for a short time, and highly accurate estimation is enabled corresponding to the amount of learning. The simulation unit again determines a polishing recipe by simulation based on corrected area response data estimated by the response data correction unit, and thus a polishing recipe can be highly accurately and efficiently determined.

A polishing recipe determination device according to fourth aspect of an embodiment is

the polishing recipe determination device according to the first aspect in which

the first learned model machine-learns the relationship between the past area response data and whether an irregularity is present and a type of an irregularity in the past area response data, and the irregularity-presence-or-absence estimation unit estimates and outputs presence or absence of an irregularity and a type of the irregularity using new area response data as an input, and

the second learned model machine-learns the relationship between the past area response data with an irregularity, a type of an irregularity, and the area response data after the removal of the irregularity, and the screening unit estimates and outputs, when the irregularity-presence-or-absence estimation unit estimates that an irregularity is present, area response data after removal of the irregularity using area response data estimated that an irregularity is present and an estimated type of an irregularity as an input.

According to such an aspect, the screening unit performs estimation to area response data estimated that an irregularity is present also using information about a type of an irregularity of the area response data, and thus the area response data after the removal of the irregularity can be much highly accurately estimated. Accordingly, a much highly accurate determination of the polishing recipe can be achieved.

A polishing recipe determination device according to a fifth aspect of an embodiment is the polishing recipe determination device according to the fourth aspect, in which

the type of an irregularity includes one or more than one of an asymmetric irregular point, an edge irregular point at time of applying a pressure to a center area, and a polar irregular point.

A polishing recipe determination device according to a sixth aspect of an embodiment is a polishing recipe determination device according to any one of the first to fifth aspects, in which

the response data is data that a variation in an amount of removal by polishing is divided by a variation in an air bag pressure on positions on a wafer.

A polishing recipe determination device according to a seventh aspect of an embodiment is the polishing recipe determination device according to any one of the first to fifth aspects, in which

the response data is data that a variation in a polishing removal rate is divided by a variation in an air bag pressure on positions on a wafer.

A polishing recipe determination device according to an eighth aspect of an embodiment is the polishing recipe determination device according to any one of the first to fifth aspects, in which

the response data is data that on positions on a wafer, a variation in a remaining film on the wafer is divided by a variation in an air bag pressure.

A polishing apparatus according to a ninth aspect of an embodiment includes the polishing recipe determination device according to any one of the first to the eight aspects.

A polishing recipe determination method according to a tenth aspect of an embodiment is

a polishing recipe determination method for determining a polishing recipe based on area response data acquired by changing a pressure for each area in a top ring, the response data being data that in regard to positions on a wafer, a variation in a polishing removal rate is divided by a variation in an air bag pressure, the method including the steps of:

estimating and outputting presence or absence of an irregularity by an irregularity-presence-or-absence estimation unit having a first learned model machine-learning relationship between past area response data and whether an irregularity is present in the past area response data using new area response data as an input;

estimating and outputting, when the irregularity-presence-or-absence estimation unit estimates that an irregularity is present, area response data after removal of the irregularity by a screening unit having a second learned model machine-learning relationship between past area response data with an irregularity and area response data after removal of an irregularity using area response data estimated that an irregularity is present as an input; and

determining a polishing recipe by simulation by the simulation unit based on area response data estimated that no irregularity is present by the irregularity-presence-or-absence estimation unit, or area response data after the removal of the irregularity estimated by a screening unit.

A polishing recipe determination method according to an eleventh aspect is the polishing recipe determination method according to the tenth aspect of the embodiment, further including the steps of:

comparing an actual polishing result obtained by actually polishing using the polishing recipe with a simulation polishing result obtained by simulation using the polishing recipe by an acceptance evaluation unit to evaluate an acceptance of the actual polishing result;

estimating and outputting, when the acceptance evaluation unit evaluates non-acceptance, corrected area response data by a response data correction unit having a third learned model machine-learning relationship between a past actual polishing result, a simulation polishing result, area response data used for determination of a polishing recipe at that time, and corrected area response data using an actual polishing result evaluated as non-acceptance, a simulation polishing result, and area response data used for the determination of a polishing recipe at that time as an input; and

again determining a polishing recipe by simulation by the simulation unit based on the corrected area response data estimated by the response data correction unit.

A polishing recipe determination method according to a twelfth aspect of an embodiment is

a polishing recipe determination method for determining a polishing recipe based on area response data acquired by changing a pressure for each area in a top ring, the method comprising the steps of:

determining a polishing recipe by simulation by a simulation unit based on new area response data;

comparing an actual polishing result obtained by actually polishing using the polishing recipe with a simulation polishing result obtained by simulation using the polishing recipe by an acceptance evaluation unit to evaluate an acceptance of the actual polishing result;

estimating and outputting, when the acceptance evaluation unit evaluates non-acceptance, corrected area response data by a response data correction unit having a third learned model machine-learning relationship between a past actual polishing result, a simulation polishing result, area response data used for determination of a polishing recipe at that time, and corrected area response data using an actual polishing result evaluated as non-acceptance, the simulation polishing result, and area response E data used for determination of a polishing recipe at that time as an input; and

again determining a polishing recipe by simulation by the simulation unit based on the corrected area response data estimated by the response data correction unit.

A polishing recipe determination program according to a thirteenth aspect of an embodiment is

a polishing recipe determination program causing a computer to execute a process for determining a polishing recipe based on area response data acquired by changing a pressure for each area in a top ring, the program causing the computer to execute the steps of:

estimating and outputting presence or absence of an irregularity by an irregularity-presence-or-absence estimation unit having a first learned model machine-learning relationship between past area response data and whether an irregularity is present in the past area response data using new area response data as an input;

estimating and outputting, when the irregularity-presence-or-absence estimation unit estimates that an irregularity is present, area response data after removal of the irregularity by a screening unit having a second learned model machine-learning relationship between past area response data with an irregularity and area response data after removal of an irregularity using area response data estimated that an irregularity is present as an input; and

determining a polishing recipe by simulation by the simulation unit based on area response data estimated that no irregularity is present by the irregularity-presence-or-absence estimation unit, or area response data after the removal of the irregularity estimated by a screening unit.

A polishing recipe determination program according to a fourteenth aspect of an embodiment is the polishing recipe determination program according to the thirteenth aspect in which

the program further causes the computer to execute the steps of:

comparing an actual polishing result obtained by actually polishing using the polishing recipe with a simulation polishing result obtained by simulation using the polishing recipe by an acceptance evaluation unit to evaluate an acceptance of the actual polishing result;

estimating and outputting, when the acceptance evaluation unit evaluates non-acceptance, corrected area response data by a response data correction unit having a third learned model machine-learning relationship between a past actual polishing result, a simulation polishing result, area response data used for determination of a polishing recipe at that time, and corrected area response data using an actual polishing result evaluated as non-acceptance, a simulation polishing result, and area response data used for the determination of a polishing recipe at that time as an input; and

again determining a polishing recipe by simulation by the simulation unit based on the corrected area response data estimated by the response data correction unit.

A polishing recipe determination program according to a fifteenth aspect of an embodiment is

a polishing recipe determination program causing a computer to execute a process for determining a polishing recipe based on area response data acquired by changing a pressure for each area in a top ring, the response data being data that in regard to positions on a wafer, a variation in a polishing removal rate is divided by a variation in an air bag pressure, the program causing the computer to execute the steps of:

determining a polishing recipe by simulation by a simulation unit based on new area response data;

comparing an actual polishing result obtained by actually polishing using the polishing recipe with a simulation polishing result obtained by simulation using the polishing recipe by an acceptance evaluation unit to evaluate an acceptance of the actual polishing result;

estimating and outputting, when the acceptance evaluation unit evaluates non-acceptance, corrected area response data by a response data correction unit having a third learned model machine-learning relationship between a past actual polishing result, a simulation polishing result, area response data used for determination of a polishing recipe at that time, and corrected area response data using an actual polishing result evaluated as non-acceptance, a simulation polishing result, and area response data used for the determination of a polishing recipe at that time as an input; and

again determining a polishing recipe by simulation by the simulation unit based on the corrected area response data estimated by the response data correction unit.

A computer-readable recording medium according to a sixteenth aspect of an embodiment is

a computer-readable recording medium recording, in a non-transitory manner, a program causing a computer to execute a process for determining a polishing recipe based on area response data acquired by changing a pressure for each area in a top ring, the program causing the computer to execute the steps of:

estimating and outputting presence or absence of an irregularity by an irregularity-presence-or-absence estimation unit having a first learned model machine-learning relationship between past area response data and whether an irregularity is present in the past area response data using new area response data as an input;

estimating and outputting, when the irregularity-presence-or-absence estimation unit estimates that an irregularity is present, area response data after removal of the irregularity by a screening unit having a second learned model machine-learning relationship between past area response data with an irregularity and area response data after removal of an irregularity using area response data estimated that an irregularity is present as an input; and

determining a polishing recipe by simulation by the simulation unit based on area response data estimated that no irregularity is present by the irregularity-presence-or-absence estimation unit, or area response data after the removal of the irregularity estimated by a screening unit.

A computer-readable recording medium according to a seventeenth aspect of an embodiment is the computer-readable recording medium according to the sixteenth aspect in which

the program further causes the computer to execute the steps of:

comparing an actual polishing result obtained by actually polishing using the polishing recipe with a simulation polishing result obtained by simulation using the polishing recipe by an acceptance evaluation unit to evaluate an acceptance of the actual polishing result;

estimating and outputting, when the acceptance evaluation unit evaluates non-acceptance, corrected area response data by a response data correction unit having a third learned model machine-learning relationship between a past actual polishing result, a simulation polishing result, area response data used for determination of a polishing recipe at that time, and corrected area response data using an actual polishing result evaluated as non-acceptance, a simulation polishing result, and area response data used for the determination of a polishing recipe at that time as an input; and

again determining a polishing recipe by simulation by the simulation unit based on the corrected area response data estimated by the response data correction unit.

A computer-readable recording medium according to an eighteenth aspect of an embodiment is

a computer-readable recording medium recording, in a non-transitory manner, a program causing a computer to execute a process for determining a polishing recipe based on area response data acquired by changing a pressure for each area in a top ring, the program causing the computer to execute the steps of:

determining a polishing recipe by simulation by a simulation unit based on new area response data;

comparing an actual polishing result obtained by actually polishing using the polishing recipe with a simulation polishing result obtained by simulation using the polishing recipe by an acceptance evaluation unit to evaluate an acceptance of the actual polishing result;

estimating and outputting, when the acceptance evaluation unit evaluates non-acceptance, corrected area response data by a response data correction unit having a third learned model machine-learning relationship between a past actual polishing result, a simulation polishing result, area response data used for determination of a polishing recipe at that time, and corrected area response data using an actual polishing result evaluated as non-acceptance, a simulation polishing result, and area response data used for the determination of a polishing recipe at that time as an input; and

again determining a polishing recipe by simulation by the simulation unit based on the corrected area response data estimated by the response data correction unit.

In the following, specific examples of an embodiment will be described in detail with reference to the accompanying drawings. It should be noted that in the following description and the drawings used in the following description, parts that are possibly formed in the same configuration are designated with the same reference signs, and the redundant description is omitted.

<Information Processing System>

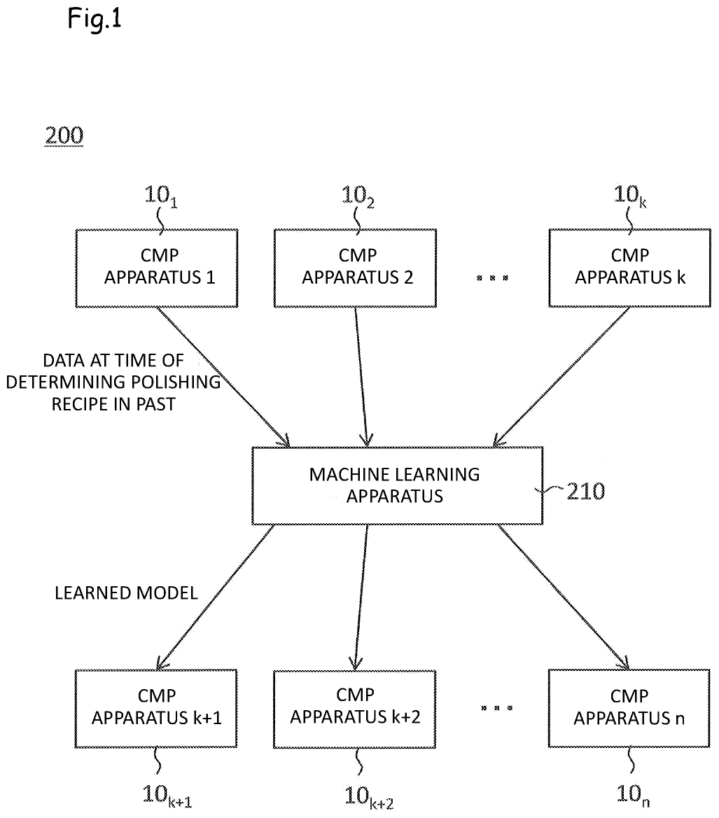

FIG. 1 is a schematic diagram that illustrates the configuration of an information processing system 200 according to an embodiment.

As illustrated in FIG. 1, the information processing system 200 has a plurality of polishing apparatuses 10₁ to 10ₙ (in the following, sometimes referred to as CMP apparatuses) that performs chemical-mechanical polishing (CMP), and a machine learning apparatus 210 connected to the polishing apparatuses 10₁ to 10ₙ via a network, the machine learning apparatus 210 being capable of communicating with the polishing apparatuses 10₁ to 10ₙ.

The machine learning apparatus 210 is a cloud type computer system or a quantum computing system, for example, and the machine learning apparatus 210 acquires data used at the time of past polishing recipe determination from one or more than one of polishing apparatuses 10₁ to 10ₖ for which a polishing recipe is determined by an engineer to perform machine learning, and distributes a learned model (e.g., a tuned neural network system) as a learning result to one or more than one of polishing apparatuses 10ₖ₊₁ to 10ₙ.

Here, data at the time of determining a polishing recipe in the past to be transmitted from the polishing apparatuses 10₁ to 10ₖ to the machine learning apparatus 210 includes, for example, area response data acquired by changing a pressure for each pressure chamber of a top ring, a controllable parameter at the time of acquiring the area response data, an evaluation result obtained by evaluating the presence or absence of an irregularity by an engineer to area response data, a discrimination result obtained by discriminating the type of irregularity by the engineer, area response data after the removal of an irregularity to which data is compensated and removed by the engineer, and corrected area response data, which is corrected by the engineer in consideration of a difference between an actual polishing result and a simulation polishing result to area response data used for determining a polishing recipe. The controllable parameters may include pressures relating to a plurality of pressure chambers in the top ring applying a pressure to a plurality of areas. The controllable parameter may include a pressure relating to the pressure chamber in the top ring applying a pressure to a retainer ring of the top ring. The plurality of areas may be disposed concentrically, and a plurality of positions may be radial distances from the center of a wafer. The plurality of positions (the positions of the wafer) may include a first plurality of positions located below a first area of the plurality of areas and a second plurality of positions located below a second area of the plurality of areas. The controllable parameter may include a polishing table rotation speed or a top ring rotation speed. The wafer positions may be regularly spaced across the surface of the wafer. A large number of positions may be present more than the number of parameters. The controllable parameter may include one or more than one a process species (film species of the surface of the wafer), a pressure for each area of an air bag, a polishing time period, a polishing pad use time, a polishing pad temperature, the supply amount, temperature, or supply/stop timing of a polishing liquid (polishing slurry), one or both of the rotation speed and rotation speed of the polishing table, one or both of the rotation speed and the rotation speed of the top ring, and retainer ring use time.

The machine learning apparatus 210 according to the present embodiment includes a first machine learning unit that creates a first learned model, a second machine learning unit that creates a second learned model, and a third machine learning unit that creates a third learned model. Learning methods for the learned models may be supervised learning or unsupervised learning.

The first machine learning unit includes, for example, a hierarchical neural network or a quantum neural network (QNN) having an input layer, one or more than one of intermediate layers connected to the input layer, and an output layer connected to the intermediate layer. The first machine learning unit repeats a process to a plurality of pieces of area response data acquired from the polishing apparatus 10₁ to 10ₖ in which area response data acquired from the polishing apparatuses 10₁ to 10ₖ (or area response data acquired from the polishing apparatuses 10₁ to 10ₖ and the controllable parameter at the time of acquiring the area response data) is inputted to the input layer, compares an output result thus outputted from the output layer with an evaluation result in which the engineer evaluates the presence or absence of an irregularity on the area response data, and updates the parameters (a weight, a threshold, and any other parameter) of nodes. Thus, a first learned model is created, the first learned model machine-learning the relationship between past area response data (or past area response data and the controllable parameter at the time of acquiring the area response data) and whether an irregularity is present in the past area response data.

As an exemplary modification, the first machine learning unit may be created a first learned model machine-learning by repeating a process on a plurality of pieces of area response data acquired from the polishing apparatuses 10₁ to 10ₖ in which area response data acquired from the polishing apparatuses 10₁ to 10ₖ (or area response data acquired from the polishing apparatuses 10₁ to 10ₖ and the controllable parameter at the time of acquiring the area response data) is inputted to the input layer, an output result thus outputted from the output layer is compared with an evaluation result in which the engineer evaluates the presence or absence of an irregularity and a type of the irregularity on the area response data, and the parameter (a weight, a threshold, and any other parameter) of the nodes is updated corresponding to an error in the comparison, the first learned model machine-learning the relationship between the past area response data (or the past area response data and the controllable parameter at the time of acquiring the area response data) and whether an irregularity is present in the past area response data and a type of an irregularity.

The second machine learning unit includes, for example, a hierarchical neural network or a quantum neural network (QNN) including an input layer, one or more than one of intermediate layers connected to the input layer, and an output layer connected to the intermediate layer. The second machine learning unit repeats a process to a plurality of pieces of area response data acquired from the polishing apparatuses 10₁ to 10ₖ in which past area response data evaluated by the engineer that an irregularity is present (or past area response data evaluated by the engineer that an irregularity is present and the controllable parameter at the time of acquiring the area response data) is inputted to the input layer, an output result thus outputted from the output layer is compared with the area response data after the removal of the irregularity to which the engineer performs the complementation and removal of data. Thus, a second learned model machine-learning the relationship between the past area response data with an irregularity (or the past area response data with an irregularity and the controllable parameter at the time of acquiring the area response data) and the area response data after the removal of the irregularity is created.

As an exemplary modification, the second machine learning unit repeats a process on a plurality of pieces of area response data acquired from the polishing apparatuses 10₁ to 10ₖ in which the past area response data evaluated by the engineer that an irregularity is present and a type of an irregularity of the past area response data (or the past response area response data for each area evaluated by the engineer that an irregularity is present and a type of an irregularity of the area response data and the controllable parameter at the time of acquiring the area response data) are inputted to the input layer an output result thus outputted from the output layer is compared with the area response data after the removal of the irregularity to which the engineer performs the complementation and removal of data, and the parameter (a weight, a threshold, and any other parameter) of the nodes is updated corresponding to an error in the comparison, and thus a second learned model may be created, the second learned model machine-learning the relationship between the past area response data with an irregularity, a type of an irregularity (or the past area response data with an irregularity and a type of the irregularity and the controllable parameter at the time of acquiring the area response data), and the area response data after the removal of the irregularity.

The third machine learning unit includes, for example, a hierarchical neural network or a quantum neural network (QNN) including an input layer, one or more than one of intermediate layers connected to the input layer, and an output layer connected to the intermediate layer. The third machine learning unit repeats a process on a plurality of pieces of area response data acquired from the polishing apparatuses 10₁ to 10ₖ in which a past actual polishing result, a simulation polishing result, and area response data used for the determination of a polishing recipe at that time (or a past actual polishing result, a simulation polishing result, and the area response data used for the determination of a polishing recipe at that time and the controllable parameter at the time of acquiring the area response data) are inputted to the input layer, the output result thus outputted from the output layer is compared with the corrected area response data corrected by the engineer in consideration of a difference between the actual polishing result and the simulation polishing result on the area response data, and the parameter (a weight, a threshold, and any other parameter) of the nodes is updated corresponding to an error in the comparison. Thus, a third learned model is created, the third learned model machine-learning the relationship between the past actual polishing result, the simulation polishing result, the area response data used for the determination of a polishing recipe at that time (or the past actual polishing result, the simulation polishing result, and the area response data used for the determination of a polishing recipe at that time and the controllable parameter at the time of acquiring the area response data), and the corrected area response data.

As illustrated in FIG. 1, one or more than one of the polishing apparatuses 10ₖ₊₁ to 10ₙ acquire the first to third learned models as learning results from the machine learning apparatus 210.

<Polishing Apparatus>

Next, the configurations of the polishing apparatuses 10ₖ₊₁ to 10ₙ having the learned model acquired from the machine learning apparatus 210 will be described with reference sign 10.

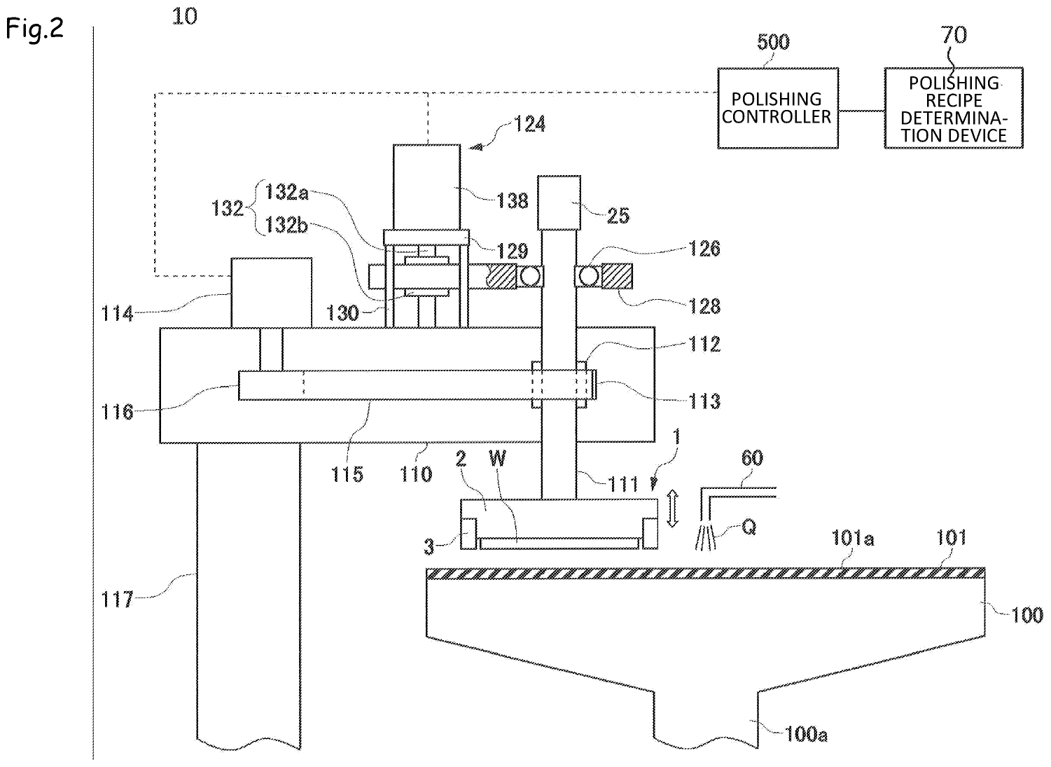

FIG. 2 is a schematic diagram showing a configuration of the polishing apparatus 10. As illustrated in FIG. 2, the polishing apparatus 10 includes a polishing table 100, a top ring 1 as a substrate holding device that holds presses a substrate such as a semiconductor wafer, which is a polishing target, against a polishing surface on the polishing table 100, a polishing controller 500, and a polishing recipe determination device 70.

The polishing table 100 is coupled, thorough a table shaft 100a, to a motor (not illustrated) disposed below the table shaft 100a. The polishing table 100 rotates about the table shaft 100a by rotating the motor. To the top surface of the polishing table 100, a polishing pad 101 as a polishing member is attached. A surface 101a of the polishing pad 101 forms a polishing surface that polishes a semiconductor wafer W. Above the polishing table 100, a polishing liquid supply nozzle 60 is installed. From the polishing liquid supply nozzle 60, a polishing liquid (polishing slurry) Q is supplied onto the polishing pad 101 on the polishing table 100.

The top ring 1 is basically composed of a top ring main body 2 that presses the semiconductor wafer W against the polishing surface 101a and a retainer ring 3, as a retainer member, that holds the outer circumferential edge of the semiconductor wafer W to stop the semiconductor wafer W from being ejected from the top ring 1. The top ring 1 is connected to a top ring shaft 111. The top ring shaft 111 vertically moves to a top ring head 110 by a vertical motion mechanism 124. The positioning of the top ring 1 in the vertical direction is performed by the top ring shaft 111 in vertical motion while the entire top ring 1 is elevated to the top ring head 110. To the top end the top ring shaft 111, a rotary joint 25 is mounted.

The vertical motion mechanism 124 that vertically moves the top ring shaft 111 and the top ring 1 includes a bridge 128 that rotatably supports the top ring shaft 111 through a bearing 126, a ball screw 132 mounted on the bridge 128, a support base 129 supported by the post 130, and an AC servo motor 138 provided on the support base 129. The support base 129 supporting the servo motor 138 is fixed to the top ring head 110 through the post 130.

The ball screw 132 includes a screw rod 132a coupled to the servo motor 138 and a nut 132b to which this screw rod 132a is screwed. The top ring shaft 111 vertically moves integrally with the bridge 128. Therefore, in the case in which the servo motor 138 is driven, the bridge 128 vertically moves through the ball screw 132, and thus the top ring shaft 111 and the top ring 1 vertically move.

The top ring shaft 111 is coupled to a rotating cylinder 112 through a key (not illustrated). The rotating cylinder 112 includes a timing pulley 113 on the outer circumferential part of the rotating cylinder 112. To the top ring head 110, a top ring rotating motor 114 is fixed, and the timing pulley 113 is connected to a timing pulley 116 provided on the top ring rotating motor 114 through a timing belt 115. Therefore, the top ring rotating motor 114 is rotated and driven to rotate the rotating cylinder 112 and the top ring shaft 111 integrally through the timing pulley 116, the timing belt 115, and the timing pulley 113, and the top ring 1 is rotated. The top ring head 110 is supported by a top ring head shaft 117 rotatably supported on a frame (not illustrated).

The polishing controller 500 controls devices in the apparatus including the top ring rotating motor 114, the servo motor 138, and the polishing table rotating motor.

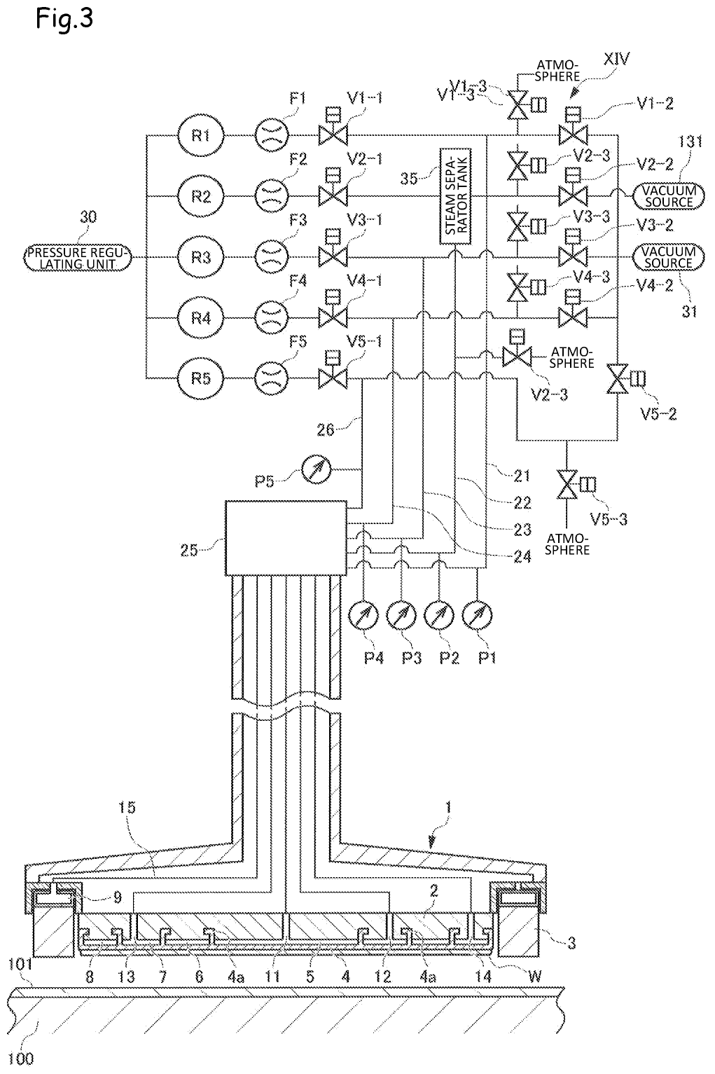

FIG. 3 is a schematic cross sectional view that illustrates the internal configuration of the top ring 1. FIG. 3 illustrates main components alone that constitute the top ring 1.

As illustrated in FIG. 3, the top ring 1 has the top ring main body (also referred to as a carrier) 2 that presses the semiconductor wafer W against the polishing surface 101a and the retainer ring 3, as a retainer member, that directly presses the polishing surface 101a.

The top ring main body (carrier) 2 formed of a member in a near disc shape, and the retainer ring 3 is mounted on the outer circumferential part of the top ring main body 2.

The top ring main body 2 is made of a resin such as an engineering plastic (e.g., PEEK).

On the under surface of the top ring main body 2, an elastic film (membrane) 4 in contact with the back surface of the semiconductor wafer is mounted. The elastic film (membrane) 4 is formed of a rubber material such as ethylene propylene rubber (EPDM), polyurethane rubber, and silicone rubber of excellent strength and durability. The elastic film (membrane) 4 forms a substrate holding surface holding a substrate such as a semiconductor wafer.

The elastic film (membrane) 4 has a plurality of partitions 4a in a concentric shape, and these partitions 4a form, between the top surface of the membrane 4 and the under surface of the top ring main body 2, a center chamber 5 in a circular shape, a ripple chamber 6 in an annular shape, an outer chamber 7 in an annular shape, and an edge chamber 8 in an annular shape. That is, the center chamber 5 is formed in the center part of the top ring main body 2, and the ripple chamber 6, the outer chamber 7, and the edge chamber 8 are formed in a concentric shape sequentially from the center to the outer circumferential direction. In the top ring main body 2, a passage 11 communicating with the center chamber 5, a passage 12 communicating with the ripple chamber 6, the passage 13 communicating with the outer chamber 7, the passage 14 communicating with the edge chamber 8 are formed.

The passage 11 communicating with the center chamber 5, the passage 13 communicating with the outer chamber 7, and the passage 14 communicating with the edge chamber 8 are, respectively, connected to passages 21, 23, and 24 through the rotary joint 25. The passages 21, 23, and 24 are connected to a pressure regulating unit 30 respectively through valves V1-1, V3-1, and V4-1 and pressure regulators R1, R3, and R4. The passages 21, 23, and 24 are connected to a vacuum source 31 respectively through valves V1-2, V3-2, and V4-2 and capable of communicating with the atmosphere through valves V1-3, V3-3, and V4-3.

On the other hand, the passage 12 communicating with the ripple chamber 6 is connected to a passage 22 through the rotary joint 25. The passage 22 is connected to the pressure regulating unit 30 through a steam separator tank 35, a valve V2-1, and a pressure regulator R2. The passage 22 is connected to a vacuum source 131 through the steam separator tank 35 and a valve V2-2, and is capable of communicating with the atmosphere through a valve V2-3.

Also right above the retainer ring 3, a retainer ring pressure chamber 9 is formed with an elastic film (membrane) 32. The elastic film (membrane) 32 is housed in a cylinder 33 fixed to the flange part of the top ring 1. The retainer ring pressure chamber 9 is connected to a passage 26 through a passage 15 and formed in the top ring main body (carrier) 2 the rotary joint 25. The passage 26 is connected to the pressure regulating unit 30 through a valve V5-1 and a pressure regulator R5. The passage 26 is connected to the vacuum source 31 through a valve V5-2, and is capable of communicating with the atmosphere through a valve V5-3.

The pressure regulators R1, R2, R3, R4, and R5 have a pressure regulating function that regulates the pressure of a pressure fluid to be supplied from the pressure regulating unit 30 to the center chamber 5, the ripple chamber 6, the outer chamber 7, the edge chamber 8, and the retainer ring pressure chamber 9, respectively. The pressure regulators R1, R2, R3, R4, and R5 and the valves V1-1 to V1-3, V2-1 to V2-3, V3-1 to V3-3, V4-1 to V4-3, and V5-1 to V5-3 are connected to the control unit 500 (see FIG. 1) to control their operations. The passages 21, 22, 23, 24, and 26 are, respectively, installed with pressure sensors P1, P2, P3, P4, and P5 and flow sensors F1, F2, F3, F4, and F5.

The pressure of the fluid to be supplied to the center chamber 5, the ripple chamber 6, the outer chamber 7, the edge chamber 8, and the retainer ring pressure chamber 9 is independently regulated by the pressure regulating unit 30 and the pressure regulators R1, R2, R3, R4, and R5. With such a structure, the pressing force to be pressed the semiconductor wafer W against the polishing pad 101 can be regulated for each of the regions the semiconductor wafer, and the pressing force to be pressed against the polishing pad 101 by the retainer ring 3 can be regulated.

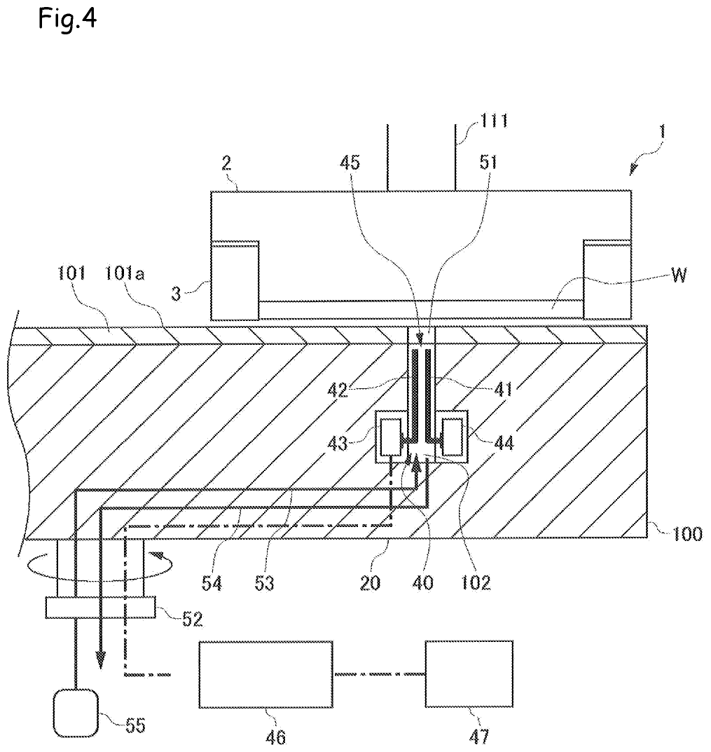

FIG. 4 is a schematic cross sectional view that illustrates the internal configuration of the polishing table 100. FIG. 4 illustrates main components alone that constitute the polishing table 100.

As illustrated in FIG. 4, a hole 102 is formed in the inside of the polishing table 100, the hole 102 opening on the top surface of the polishing table 100. In the polishing pad 101, a through hole 51 is formed at a position corresponding to the hole 102. The hole 102 communicates with the through hole 51. The through hole 51 opens on the polishing surface 101a. The hole 102 is coupled to a liquid supply source 55 through a liquid supply path 53 and a rotary joint 52. During polishing, from the liquid supply source 55, water, as transparent liquid (preferably pure water), is supplied to the hole 102. The space formed by the under surface of the semiconductor wafer W and the through hole 51 with water, and water is supplied through a liquid supply path 54. The polishing liquid is supplied together with water, and thus an optical path is reserved. The liquid supply path 53 is provided with a valve (not illustrated) operated in synchronization with the rotation of the polishing table 100. This valve operates in such a manner that the valve stops a water flow or the valve reduces the flow rate of water when the semiconductor wafer W is not located on the through hole 51.

The polishing apparatus 10 includes a film thickness measuring unit 40 that measures the film thickness of the substrate. The film thickness measuring unit 40 is an optical film thickness sensor including a light source 44 that emits a light beam, a light projecting unit 41 that applies the light beam emitted from the light source 44 onto the surface of the semiconductor wafer W, a light receiving unit 42 that receives a reflected light beam returning from the semiconductor wafer W, a spectrometer 43 that resolves the reflected light beam from the semiconductor wafer W according to wavelengths and measures the intensity of the reflected light beam across a predetermined wavelength range, and a processing unit 46 that creates a spectrum from measured data acquired by the spectrometer 43 and determines the film thickness of the semiconductor wafer W based on this spectrum. The spectrum indicates the intensity of the light beam distributed across a predetermined wavelength range, and indicates the relationship between the intensity and wavelength of the light beam.

The light projecting unit 41 and the light receiving unit 42 are formed of optical fibers. The light projecting unit 41 and the light receiving unit 42 constitute an optical head (the optical film thickness measuring head) 45 The light projecting unit 41 is connected to the light source 44. The light receiving unit 42 is connected to the spectrometer 43. As the light source 44, a light source that emits a light beam having a plurality of wavelengths such as a light emitting diode (LED), a halogen lamp, and a xenon flash lamp can be used. The light projecting unit 41, the light receiving unit 42, the light source 44, and the spectrometer 43 are disposed in the inside of the polishing table 100, and rotate together with the polishing table 100. The light projecting unit 41 and the light receiving unit 42 are disposed in the hole 102 formed in the polishing table 100, the tip ends of the light projecting unit 41 and the light receiving unit 42 are located near the polished surface of the semiconductor wafer W.

The light projecting unit 41 and the light receiving unit 42 are disposed perpendicularly to the surface of the semiconductor wafer W, and the light projecting unit 41 applies the light beam perpendicularly to the surface of the semiconductor wafer W. The light projecting unit 41 and the light receiving unit 42 are disposed opposite to the center of the semiconductor wafer W held on the top ring 1. Therefore, the light projecting unit 41 and the light receiving unit 42 move crossing the semiconductor wafer W every time when the polishing table 100 rotates, and the light beam is applied to the region including the center of the semiconductor wafer W. This is because the light projecting unit 41 and the light receiving unit 42 pass the center of the semiconductor wafer W to measure the film thickness of the entire surface of the semiconductor wafer W including the film thickness of the center part of the semiconductor wafer W. The processing unit 46 can create a film thickness profile (the distribution of the film thickness in the radial direction) based on the measured film thickness data. The processing unit 46 is connected to the polishing controller 500 (see FIG. 2), and outputs the created film thickness profile to the polishing controller 500.

During the polishing of the semiconductor wafer W, a light beam is applied to the semiconductor wafer W from the light projecting unit 41. The light beam from the light projecting unit 41 is reflected off the surface of the semiconductor wafer W, and received at the light receiving unit 42. During which the light beam is applied to the semiconductor wafer W, water is supplied to the hole 102 and the through hole 51, and thus the space between the tip ends of the light projecting unit 41 and the light receiving unit 42 and the surface of the semiconductor wafer W is filled with water. The spectrometer 43 resolves the reflected light beam sent from the light receiving unit 42 according to wavelengths, and measures the intensity of the reflected light beam for each wavelength. The processing unit 46 creates a spectrum indicating the relationship between the intensity and wavelength of the reflected light beam from the intensity of the reflected light beam measured by the spectrometer 43 and. The processing unit 46 further estimates the present film thickness profile (remaining film profile) of the semiconductor wafer W from the obtained spectrum using publicly known techniques.

The polishing apparatus 10 may include a film thickness measuring unit according to another scheme instead of the above-described film thickness measuring unit 40 formed of the optical film thickness sensor. An example of the film thickness measuring unit according to another scheme includes an eddy current film thickness sensor that is disposed in the inside of the polishing table 100 and that acquires a film thickness signal changed corresponding to the film thickness of the semiconductor wafer W. The eddy current film thickness sensor is rotated integrally with the polishing table 100, and acquires the film thickness signal of the semiconductor wafer W held on the top ring 1. The eddy current film thickness sensor is connected to the polishing controller 500 illustrated in FIG. 2, and sends the film thickness signal acquired by the eddy current film thickness sensor to the polishing controller 500. The polishing controller 500 creates a film thickness index value directly or indirectly expressing the film thickness from the film thickness signal.

The eddy current film thickness sensor is configured in which the eddy current film thickness sensor carries an alternating electric current of radio frequency through a coil to induce an eddy current on a conductive film, and detects the thickness of the conductive film from a change in the impedance due to the magnetic field of this eddy current. As an eddy current sensor, a publicly known eddy current sensor described in JP 2014-017418 A can be used.

It should be noted that in the above-described example, the through hole 51 is provided on the polishing surface 101a, the liquid supply path 53, the liquid supply path 54, and the liquid supply source 55 are provided, and the hole 102 is filled with water. However, instead of this, a transparent window may be formed on the polishing pad 101. In this case, the light projecting unit 41 applies a light beam onto the surface of the substrate W on the polishing pad 101 through this transparent window, and the light receiving unit 42 receives a reflected light beam from the semiconductor wafer W through the transparent window.

The polishing operation by the polishing apparatus 10 thus configured will be described. The top ring 1 receives the semiconductor wafer W from a substrate delivery device (pusher), and holds the semiconductor wafer W on the under surface of the top ring 1 by vacuum suction. At this time, the top ring 1 holds the top ring 1 such a manner that the polished surface (generally the surface on which devices are formed, also referred to as “s front surface”) is directed downward and the polished surface is opposite to the surface of the polishing pad 101. The top ring 1 holding the semiconductor wafer W on its under surface is moved from the position at which the semiconductor wafer W is derived to above the polishing table 100 by turning the top ring head 110 due to the rotation of the top ring head shaft 117.

The top ring 1 holding the semiconductor wafer W by vacuum suction is lowered to a preset polishing time setting position for the top ring. At the polishing time setting position, although the retainer ring 3 is grounded to the surface (polishing surface) 101a of the polishing pad 101, the semiconductor wafer W is sucked and held by the top ring 1 before polishing, and a slight gap (e.g., about one millimeter) is present between the under surface of the semiconductor wafer W (the polished surface) and the surface (polishing surface) 101a of the polishing pad 101. At this time, the polishing table 100 and the top ring 1 are both rotated and driven, and the polishing liquid is supplied onto the polishing pad 101 from the polishing liquid supply nozzle 102 provided above the polishing table 100.

In this state, the elastic film (membrane) 4 located on the back surface side of the semiconductor wafer W is swelled to press the back surface of the polished surface of the semiconductor wafer W,

the polished surface of the semiconductor wafer W is pressed against the surface (polishing surface) 101a of the polishing pad 101, the polished surface of the semiconductor wafer W and the polishing surface of the polishing pad 101 are relatively slid to each other, and the polished surface of the semiconductor wafer W is polished using the polishing surface 101a of the polishing pad 101 until a predetermined state (e.g., a predetermined film thickness) is reached. After the completion of the steps of wafer processing on the polishing pad 101, the semiconductor wafer W is sucked to the top ring 1, the top ring 1 is raised, the top ring 1 is moved to the substrate delivery device that constitutes a substrate transfer mechanism, and then the wafer W is removed (released).

<Polishing Recipe Determination Device>

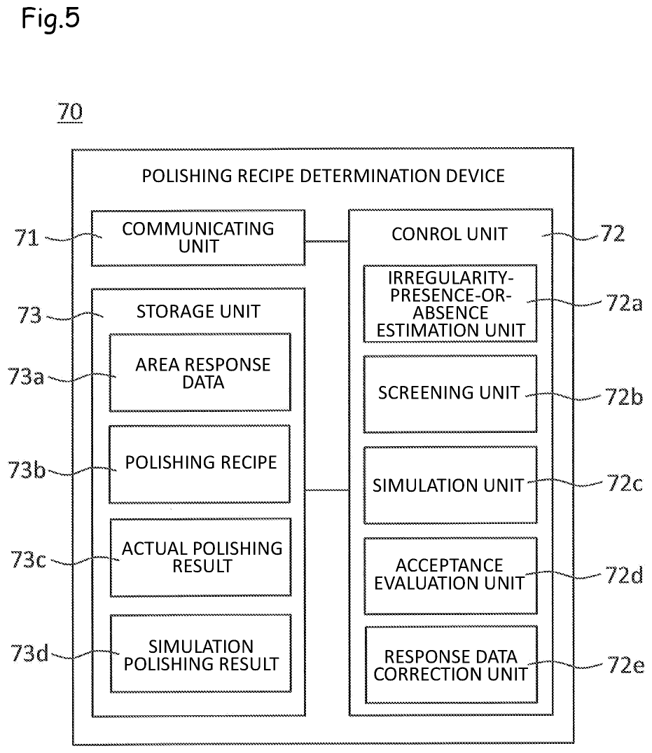

Next, the configuration of the polishing recipe determination device 70 will be described. FIG. 5 is a block diagram that illustrates the configuration of the polishing recipe determination device 70. As illustrated in FIG. 5, the polishing recipe determination device 70 has a communicating unit 71, a control unit 72, and a storage unit 73. These units are connected to each other being capable of communicating with each other through a bus.

In these units, the communicating unit 71 is a communication interface between the machine learning apparatus 210 (see FIG. 1) and the polishing controller 500 and the polishing recipe determination device 70. The communicating unit 71 transmits and receives information between the machine learning apparatus 210 and the polishing controller 500 and the polishing recipe determination device 70.

The storage unit 73 is, for example, a magnetic data storage such as a hard disk. The storage unit 73 stores various items of data handled by the control unit 72. The storage unit 73 stores area response data 73a, a polishing recipe 73b, an actual polishing result 73c, and a simulation polishing result 73d. The storage unit 73 may store controllable parameters at the time of acquiring area response data.

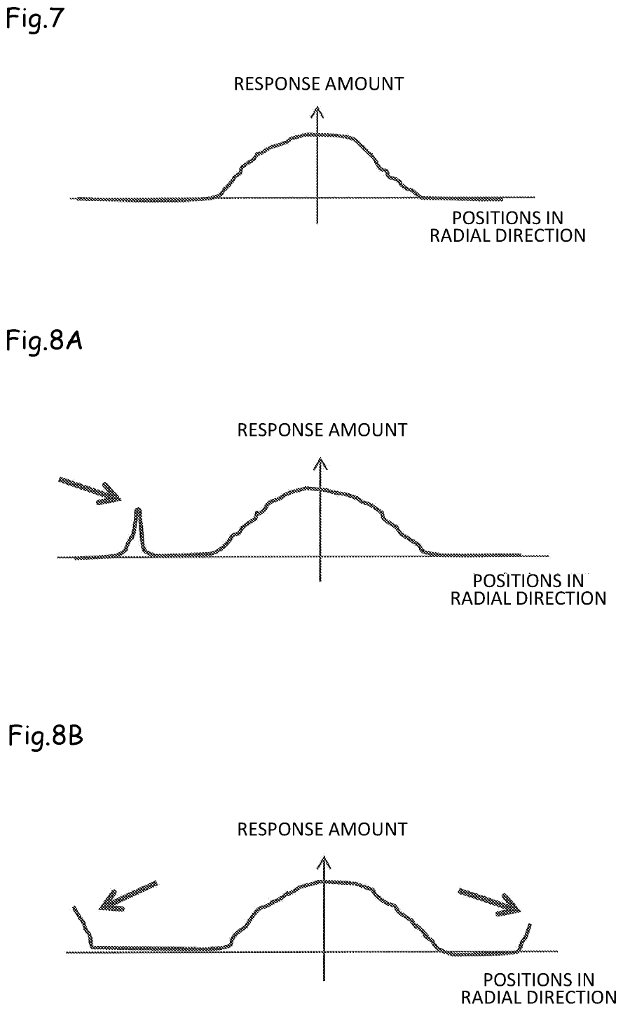

The area response data 73a is area response data acquired by a pressure variation experiment in which a test wafer is polished by changing a pressure for each of the pressure chambers 5 to 9 (areas) in the top ring 1. Here, the term “response data” means data in which a variation in the polishing removal rate at positions on a wafer is divided by a variation in an air bag pressure (=a variation ΔV in the polishing removal rate/a variation ΔP of a pressure in the pressure chambers 5 to 9). Specifically, for example, a response amount profile (response data) on the center area corresponding to the pressure chamber 5 can be obtained in which polishing removal rates V1, V2, . . . are measured at positions on the wafer when a pressure is applied to the pressure chamber 5 alone at pressures P1, P2, . . . , (P1, V1), (P2, V2), . . . are plotted at the positions on the wafer in a coordinate system where the horizontal axis is the pressure and the vertical axis is the polishing removal rates, and the slope (=response amount) of the approximation straight line of a graph in the plotting is found. FIG. 7 illustrates an example of a response amount profile of the center area. Similarly, response amount profiles (response data) can be obtained on other areas corresponding to the other pressure chambers 6 to 9 as well.

It should be noted that “response data” is not limited to data that a variation in the polishing removal rate (removal ratio) is divided by a variation in the air bag pressure on the positions on the wafer as long as factors relating to the removal amount or the remaining amount. For example, response data may be a variation in the amount of removal by polishing is divided by a variation in the air bag pressure on the positions on the wafer, or may be data that a variation in the remaining film on the wafer is divided by a variation in the air bag pressure on the positions on the wafer. Alternatively, response data may be data that the property of the remaining film (the distribution of materials other than exposed metals) is divided by a variation in the air bag pressure.

The polishing recipe 73b is data that defines various conditions when polishing is performed, and that is determined by a simulation unit 72b, described later, performing publicly known simulation based on the area response data 73a. The polishing recipe 73b may include one or more of controllable parameters for the devices in the polishing apparatus 10, for example, pressures in the pressure chambers 5 to 9 in the top ring 1, the rotation speed of the top ring 1, the rotation speed of the polishing table 100, and polishing time.

The actual polishing result 73c is a film thickness profile (remaining film profile) of the actual polishing acquired from the film thickness measuring unit 40 when the polishing controller 500 controls the devices in the polishing apparatus 10 according to the polishing recipe 73b and the wafer is polished (e.g., see a solid line graph in FIG. 9).

The simulation polishing result 73d is a film thickness profile (remaining film profile) in simulation obtained by the simulation unit 72b, described later, performing publicly known simulation under the conditions for the polishing recipe 73b (e.g., see a broken line graph in FIG. 9).

The control unit 72 is a control section that performs various processes for the polishing recipe determination device 70. As illustrated in FIG. 5, the control unit 72 has an irregularity-presence-or-absence estimation unit 72a, the screening unit 72b, a simulation unit 72c, an acceptance evaluation unit 72d, and a response data correction unit 72e. These units may be implemented by a processor in the polishing recipe determination device 70 executing a predetermined program or may be mounted by hardware.

The irregularity-presence-or-absence estimation unit 72a has the first learned model machine-learning the relationship between past area response data (or past area response data and the controllable parameter at the time of acquiring the area response data) and whether an irregularity is present in the past area response data (the first learned model acquired from the machine learning apparatus 210), and estimates and output the presence or absence of an irregularity using new area response data 73a (or new area response data and the controllable parameter at the time of acquiring the area response data) stored on the storage unit 73 as an input.

As an exemplary modification, the irregularity-presence-or-absence estimation unit 72a has the first learned model machine-learning the relationship between past area response data (or past area response data and the controllable parameter at the time of acquiring the area response data) and whether an irregularity is present in the past area response data and a type of an irregularity, and estimates and outputs the presence or absence of an irregularity and a type of the irregularity using new area response data 73a (or new area response data and the controllable parameter at the time of acquiring the area response data) stored on the storage unit 73 as an input.

FIG. 7 illustrates an example of a normal response amount profile (response data) of the center area. The irregularity-presence-or-absence estimation unit 72a can output an estimated result having no irregularity to such a normal response amount profile (response data) using the first learned model.

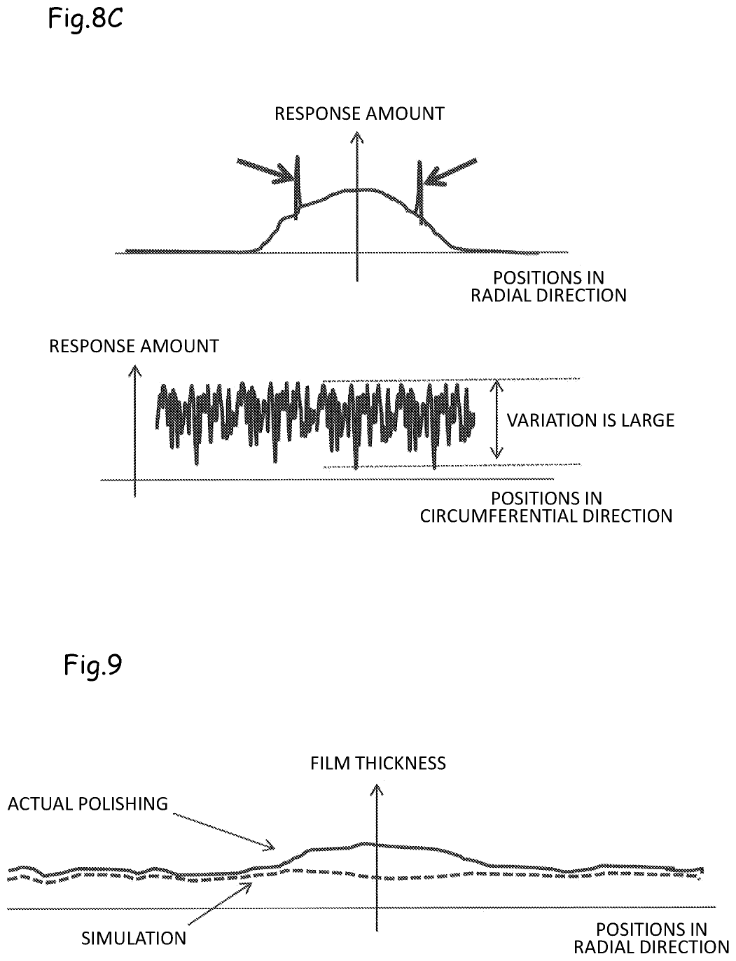

FIG. 8A illustrates an example of a response amount profile (response data) of the center area having an irregularity at the asymmetric irregular point. As indicated by arrows in FIG. 8A, in this profile, sites different in the left and the right, i.e., the asymmetric irregular points are present. The irregularity-presence-or-absence estimation unit 72a can output an estimated result having an irregularity at the asymmetric irregular points to such a response amount profile (response data) having an irregularity using the first learned model.

FIG. 8B illustrates an example of a response amount profile (response data) of the center area having an irregularity at edge irregular points at the time of applying a pressure to the center area. As indicated by arrows in FIG. 8B, in this profile, sites that respond other than the region (in this case, the center area) to which a pressure is applied, i.e., edge irregular points at the time of applying a pressure to the center area are present. The irregularity-presence-or-absence estimation unit 72a can output an estimated result having an irregularity at edge irregular points at the time of applying a pressure to the center area to such a response amount profile having an irregularity (response data) using the first learned model.

FIG. 8C illustrates an example of a response amount profile (response data) of the center area having an irregularity at polar irregular points. As indicated by arrows in the upper diagram of FIG. 8C, in this profile, data at positions in the radial direction at which the behavior in the circumferential direction is irregular, i.e., polar irregular points are present. The lower diagram of FIG. 8C illustrates a profile measured in the circumferential direction on the positions in the radial direction of the polar irregular point. The irregularity-presence-or-absence estimation unit 72a can output an estimated result having an irregularity at the polar irregular point to such a response amount profile having an irregularity (response data) using the first learned model.

The screening unit 72b has the second learned model machine-learning the relationship between past area response data with an irregularity (or past area response data with an irregularity and the controllable parameter at the time of acquiring the area response data) and area response data after the removal of the irregularity (the second learned model acquired from the machine learning apparatus 210), and in the case in which the irregularity-presence-or-absence estimation unit 72a estimates that an irregularity is present, the screening unit 72b estimates and outputs area response data after the removal of the irregularity using the area response data 73a estimated that an irregularity is present (or area response data estimated that an irregularity is present and the controllable parameter at the time of acquiring the area response data). The area response data 73a stored on the storage unit 73 is updated by the area response data after the removal of the irregularity that is estimated by the screening unit 72b.

As an exemplary modification, the screening unit 72b has the second learned model machine-learning the relationship between past area response data with an irregularity and a type of the irregularity (or past area response data with an irregularity and a type of the irregularity and the controllable parameter at the time of acquiring the area response data) and the area response data after the removal of the irregularity, and in the case in which the irregularity-presence-or-absence estimation unit 72a estimates that an irregularity is present, the screening unit 72b estimates and outputs area response data after the removal of the irregularity using the area response data 73a estimated that an irregularity is present and a type of the estimated irregularity (the asymmetric irregular point, the edge irregular point at the time of applying a pressure to the center area, the polar irregular point, and any other irregularity) (or area response data estimated that an irregularity is present and a type of the estimated irregularity and the controllable parameter at the time of acquiring the area response data) as an input. The estimation of the area response data estimated that an irregularity is present is performed also using information about a type of the irregularity is estimated, and thus the area response data after the removal of the irregularity can be much highly accurately estimated.

The simulation unit 72c determines the polishing recipe 73b performing publicly known simulation based on the area response data 73a estimated by the irregularity-presence-or-absence estimation unit 72a that no irregularity is present, or the area response data 73a after the removal of the irregularity that is estimated by the screening unit 72b. The simulation unit 72c determines the polishing recipe by simulation based on the area response data 73a (with less noise) after screening, and thus a polishing recipe can be highly accurately and efficiently determined. The polishing recipe 73b determined by the simulation unit 72c is stored on the storage unit 73.

The acceptance evaluation unit 72d compares the actual polishing result 73c obtained by actually polishing the wafer by the polishing apparatus 10 using the polishing recipe 73b determined by the simulation unit 72c with the simulation polishing result 73d obtained by simulation using the polishing recipe 73b (see FIG. 9), and evaluates the acceptance of the actual polishing result 73c based on the size of the difference. For example, in the case in which the difference of the actual polishing result 73c from the simulation polishing result 73d is a predetermined threshold or less, the acceptance evaluation unit 72d evaluates that the result is accepted, whereas in the case in which the difference is larger than the threshold, the acceptance evaluation unit 72d evaluates that the result is not accepted.

The response data correction unit 72e has the third learned model machine-learning the relationship between a past actual polishing result, a simulation polishing result, and area response data used for the determination of a polishing recipe at that time (or a past actual polishing result, a simulation polishing result, and area response data used for the determination of a polishing recipe at that time, and the controllable parameter at the time of acquiring the area response data) and the corrected area response data (the third learned model acquired from the machine learning apparatus 210), and in the case in which the acceptance evaluation unit 72d evaluates as non-acceptance, the response data correction unit 72e estimates and outputs corrected area response data using the actual polishing result 73c evaluated as non-acceptance and the simulation polishing result 73d and the area response data 72a used for the determination of a polishing recipe at that time (or an actual polishing result evaluated as non-acceptance and the simulation polishing result and the area response data used for the determination of a polishing recipe at that time and the controllable parameter at the time of acquiring the area response data) as an input. The area response data 73a stored on the storage unit 73 is updated using the corrected area response data estimated by the response data correction unit 72e.

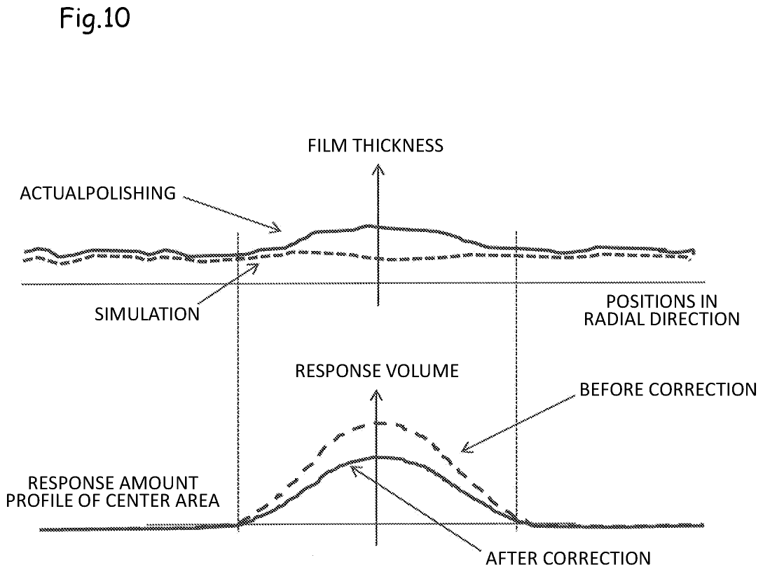

Specifically, for example, referring to FIG. 10, the remaining film profile in actual polishing (a solid line graph in the upper diagram) has the remaining film that is large in the center area (polishing is insufficient), compared with the remaining film profile in simulation (a broken line graph in the upper diagram). Using the third learned model, the response data correction unit 72e can estimate and output, to the response amount profile in the center area (a broken line graph in the lower diagram), the response amount profile (response data) (a solid line graph in the lower diagram) on the center area after correction corrected such that the response amount in the center area becomes small in consideration of a difference between the remaining film profile in actual polishing and the remaining film profile in simulation.

The simulation unit 72c again determines the polishing recipe 73b by simulation based on the corrected area response data estimated by the response data correction unit 72e 73a. The polishing recipe 73b stored on the storage unit 73 is updated by the polishing recipe again determined by the simulation unit 72c.

It should be noted that the polishing recipe determination device 70 according to the present embodiment is possibly formed of one or a plurality of computers. However, a program that causes one or a plurality of computers to implement the polishing recipe determination device 70 and a computer-readable recording medium recording the program in a non-transitory manner are also objects to be protected in the present application.

<Polishing Recipe Determination Method>

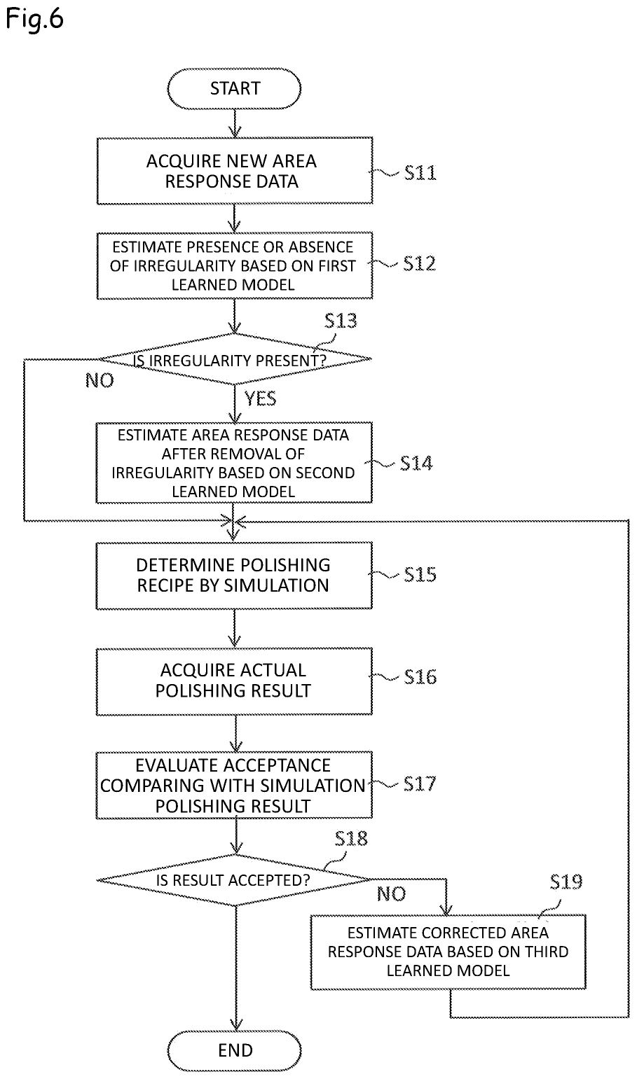

Next, an example of a polishing recipe determination method by the polishing recipe determination device 70 formed of such a configuration. FIG. 6 is a flowchart illustrating an example of a polishing recipe determination method.

As illustrated in FIG. 6, first, the polishing apparatus 10 performs a pressure variation experiment in which a test wafer is polished by changing the pressure of the fluid to be supplied for each of the pressure chambers (areas) in the top ring 1, area response data is acquired (Step S11). The acquired area response data is stored on the storage unit 73 of the polishing recipe determination device 70. The controllable parameter at the time of acquiring area response data may be stored on the storage unit 73.

Subsequently, the irregularity-presence-or-absence estimation unit 72a having the first learned model machine-learning the relationship between the past area response data (or the past area response data and the controllable parameter at the time of acquiring the area response data) and whether an irregularity is present in the past area response data estimates and outputs the presence or absence of an irregularity using new area response data 73a (or new area response data and the controllable parameter at the time of acquiring the area response data) stored on the storage unit 73 as an input (Step S12).

As an exemplary modification, the irregularity-presence-or-absence estimation unit 72a may estimate and output a type of an irregularity in addition to the presence or absence of an irregularity using new area response data 73a (or new area response data and the controllable parameter at the time of acquiring the area response data) stored on the storage unit 73 as an input based on the first learned model machine-learning the relationship between past area response data (or past area response data and the controllable parameter at the time of acquiring the area response data) and whether an irregularity is present in the past area response data and a type of an irregularity.

In the case in which the irregularity-presence-or-absence estimation unit 72a estimates that no irregularity is present (Step S13: NO), the process goes to Step S15, described later.

On the other hand, in the case in which the irregularity-presence-or-absence estimation unit 72a estimates that an irregularity is present, the screening unit 72b having the second learned model machine-learning the relationship between past area response data with an irregularity (or past area response data with an irregularity and the controllable parameter at the time of acquiring the area response data) and area response data after the removal of the irregularity estimates and outputs DOE data after the removal of the irregularity using the area response data 73a estimated that an irregularity is present (or the past area response data estimated that an irregularity is present and the controllable parameter at the time of acquiring the area response data) as an input (Step S14).

As an exemplary modification, the screening unit 72b may estimate and output area response data after the removal of the irregularity using the area response data 73a estimated that an irregularity is present and a type of the estimated irregularity (or area response data estimated that an irregularity is present and a type of the estimated irregularity and the controllable parameter at the time of acquiring the area response data) as an input based on the second learned model machine-learning the relationship between past area response data with an irregularity and a type of an irregularity (or past area response data with an irregularity and a type of the irregularity and the controllable parameter at the time of acquiring the area response data) and the area response data after the removal of the irregularity.

The area response data 73a stored on the storage unit 73 is updated by the area response data after the removal of the irregularity that is estimated by the screening unit 72b.

Subsequently, the simulation unit 72c determines the polishing recipe 73b by simulation based on the area response data 73a estimated by the irregularity-presence-or-absence estimation unit 72a that no irregularity is present, or using the area response data 73a after the removal of the irregularity that is estimated by the screening unit 72b (Step S15). The polishing recipe 73b determined by the simulation unit 72c is stored on the storage unit 73.

Subsequently, the polishing apparatus 10 actually polishes the wafer using the polishing recipe 73b determined by the simulation unit 72c, and an actual polishing result is acquired (Step S16). The acquired actual polishing result is stored on the storage unit 73 of the polishing recipe determination device 70.

Subsequently, the acceptance evaluation unit 72d compares the actual polishing result 73c with the simulation polishing result 73d obtained by simulation using the polishing recipe 73b determined by the simulation unit 72c, and evaluates the acceptance of the actual polishing result 73c based on the size of the difference (Step S17).

In the case in which the acceptance evaluation unit 72d evaluates that the result is accepted (Step S18: YES), the processes by the polishing recipe determination device 10 are ended.

On the other hand, in the case in which the acceptance evaluation unit 72d evaluates that the result is not accepted (Step S18: NO), the response data correction unit 72e having the third learned model machine-learning the relationship between a past actual polishing result, a simulation polishing result, and area response data used for the determination of a polishing recipe at that time (or a past actual polishing result, a simulation polishing result, and area response data used for the determination of a polishing recipe at that time, and the controllable parameter at the time of acquiring the area response data) and the corrected area response data estimates and outputs corrected area response data using the actual polishing result 73c evaluated as non-acceptance and the simulation polishing result 73d and the area response data used for the determination of a polishing recipe at that time 73a (or an actual polishing result evaluated as non-acceptance and the simulation polishing result and the area response data used for the determination of a polishing recipe at that time and the controllable parameter at the time of acquiring the area response data) as an input (Step S19). The area response data 73a stored on the storage unit 73 is updated using the corrected area response data estimated by the response data correction unit 72e. Returning to Step S15, the process is again performed.

That is, the simulation unit 72c again determines the polishing recipe 73b by simulation based on the corrected area response data estimated by the response data correction unit 72e 73a (Step S15). The polishing recipe 73b stored on the storage unit 73 is updated by the polishing recipe again determined by the simulation unit 72c.

According to the present embodiment as described above, since the irregularity-presence-or-absence estimation unit 72a has the first learned model machine-learning the relationship between the past area response data (or the past area response data and the controllable parameter at the time of acquiring the area response data) and the presence or absence of an irregularity, whether an irregularity is present in new area response data 73a (or new area response data and the controllable parameter at the time of acquiring the area response data) can be estimated for a short time, and highly accurate estimation is enabled corresponding to the amount of learning. Since the screening unit 72b has the second learned model machine-learning the relationship between past area response data with an irregularity (or past area response data with an irregularity and the controllable parameter at the time of acquiring the area response data) and area response data after the removal of the irregularity, the area response data after the removal of the irregularity can be estimated for a short time from the area response data 73a estimated that an irregularity is present (or area response data estimated that an irregularity is present and the controllable parameter at the time of acquiring the area response data), and highly accurate estimation is enabled corresponding to the amount of learning. The simulation unit 72c determines the polishing recipe by simulation based on the area response data 73a (with less noise) after screening, and thus a polishing recipe can be highly accurately and efficiently determined.

According to the present embodiment, since the response data correction unit 72e has the third learned model machine-learning the relationship between a past actual polishing result, a simulation polishing result, and area response data used for the determination of a polishing recipe at that time (or a past actual polishing result, a simulation polishing result, and area response data used for the determination of a polishing recipe at that time, and the controllable parameter at the time of acquiring the area response data) and the corrected area response data, corrected area response data can be estimated for a short time, and highly accurate estimation is enabled corresponding to the amount of learning the actual polishing result 73c evaluated as non-acceptance and the simulation polishing result 73d and the area response data 73a used for the determination of the polishing recipe 73c at that time (or an actual polishing result evaluated as non-acceptance and the simulation polishing result and the area response data used for the determination of a polishing recipe at that time and the controllable parameter at the time of acquiring the area response data). The simulation unit 72c again determines a polishing recipe by simulation based on the corrected area response data 73a estimated by the response data correction unit 73e, and thus a much highly accurate determination of the polishing recipe can be achieved.

As described above, although the embodiment and the exemplary modifications are described by examples, the scope of the present invention is not limited to the embodiment and the exemplary modifications, and it is possible to modify and alter the present invention according the applications within the scope described in claims. It is possible to appropriately combine the embodiment and the exemplary modifications in the scope with no contradiction in the content of the processes.

1. A polishing recipe determination device determining a polishing recipe based on area response data acquired by changing a pressure for each area in a top ring, the device comprising:
an irregularity-presence-or-absence estimation unit having a first learned model machine-learning relationship between past area response data and whether an irregularity is present in the past area response data, the irregularity-presence-or-absence estimation unit being configured to estimate and output presence or absence of an irregularity using new area response data as an input;
a screening unit having a second learned model machine-learning relationship between the past area response data with an irregularity and area response data after removal of an irregularity, the screening unit being configured to, when the irregularity-presence-or-absence estimation unit estimates that an irregularity is present, estimate area response data after the removal of the irregularity using an input of area response data estimated that an irregularity is present; and
a simulation unit configured to determine a polishing recipe by simulation based on area response data estimated that no irregularity is present by the irregularity-presence-or-absence estimation unit, or area response data after the removal of the irregularity estimated by the screening unit.

2. The polishing recipe determination device according to claim 1, further comprising:
an acceptance evaluation unit configured to compare an actual polishing result obtained by actually polishing using the polishing recipe with a simulation polishing result obtained by simulation using the polishing recipe to evaluate an acceptance of the actual polishing result;
a response data correction unit having a third learned model machine-learning relationship between a past actual polishing result, a simulation polishing result, area response data used for determination of a polishing recipe at that time; and corrected area response data, the response data correction unit being configured to, when the acceptance evaluation unit evaluates non-acceptance, estimate and output corrected area response data using an actual polishing result evaluated as non-acceptance, a simulation polishing result, and area response data used for determination of a polishing recipe at that time as an input, wherein
the simulation unit again determines a polishing recipe by simulation based on corrected area response data estimated by the response data correction unit.

3. A polishing recipe determination device determining a polishing recipe based on area response data acquired by changing a pressure for each area in a top ring, the device comprising:
a simulation unit configured to determine a polishing recipe by simulation based on new area response data;
an acceptance evaluation unit configured to compare an actual polishing result obtained by actually polishing using the polishing recipe with a simulation polishing result obtained by simulation using the polishing recipe to evaluate an acceptance of the actual polishing result; and
a response data correction unit having a third learned model machine-learning relationship between a past actual polishing result, a simulation polishing result, area response data used for determination of a polishing recipe at that time, and corrected area response data, the response data correction unit being configured to, when the acceptance evaluation unit evaluates non-acceptance, estimate and output corrected area response data using an actual polishing result evaluated as non-acceptance, a simulation polishing result, and area response data used for determination of a polishing recipe at that time as an input, wherein
the simulation unit again determines a polishing recipe by simulation based on corrected area response data estimated by the response data correction unit.

4. The polishing recipe determination device according to claim 1, wherein
the first learned model machine-learns the relationship between the past area response data and whether an irregularity is present and a type of an irregularity in the past area response data, and the irregularity-presence-or-absence estimation unit estimates and outputs presence or absence of an irregularity and a type of the irregularity using new area response data as an input, and
the second learned model machine-learns the relationship between the past area response data with an irregularity, a type of an irregularity, and the area response data after the removal of the irregularity, and the screening unit estimates and outputs, when the irregularity-presence-or-absence estimation unit estimates that an irregularity is present, area response data after removal of the irregularity using area response data estimated that an irregularity is present and an estimated type of an irregularity as an input.

5. The polishing recipe determination device according to claim 4,
wherein the type of an irregularity includes one or more than one of an asymmetric irregular point, an edge irregular point at time of applying a pressure to a center area, and a polar irregular point.

6. The polishing recipe determination device according to claim 1, wherein the response data is data that a variation in an amount of removal by polishing is divided by a variation in an air bag pressure on positions on a wafer.

7. The polishing recipe determination device according to claim 1, wherein the response data is data that a variation in a polishing removal rate is divided by a variation in an air bag pressure on positions on a wafer.

8. The polishing recipe determination device according to claim 1, wherein the response data is data that on positions on a wafer, a variation in a remaining film on the wafer is divided by a variation in an air bag pressure.

9. A polishing apparatus comprising the polishing recipe determination device according to claim 1.

10. A polishing recipe determination method for determining a polishing recipe based on area response data acquired by changing a pressure for each area in a top ring, the method comprising the steps of:
estimating and outputting presence or absence of an irregularity by an irregularity-presence-or-absence estimation unit having a first learned model machine-learning relationship between past area response data and whether an irregularity is present in the past area response data using new area response data as an input;
estimating and outputting, when the irregularity-presence-or-absence estimation unit estimates that an irregularity is present, area response data after removal of the irregularity by a screening unit having a second learned model machine-learning relationship between past area response data with an irregularity and area response data after removal of an irregularity using area response data estimated that an irregularity is present as an input; and
determining a polishing recipe by simulation by the simulation unit based on area response data estimated that no irregularity is present by the irregularity-presence-or-absence estimation unit, or area response data after the removal of the irregularity estimated by a screening unit.

11. The polishing recipe determination method according to claim 10, further comprising the steps of:
comparing an actual polishing result obtained by actually polishing using the polishing recipe with a simulation polishing result obtained by simulation using the polishing recipe by an acceptance evaluation unit to evaluate an acceptance of the actual polishing result;
estimating and outputting, when the acceptance evaluation unit evaluates non-acceptance, corrected area response data by a response data correction unit having a third learned model machine-learning relationship between a past actual polishing result, a simulation polishing result, area response data used for determination of a polishing recipe at that time, and corrected area response data using an actual polishing result evaluated as non-acceptance, a simulation polishing result, and area response data used for the determination of a polishing recipe at that time as an input; and
again determining a polishing recipe by simulation by the simulation unit based on the corrected area response data estimated by the response data correction unit.

12. A polishing recipe determination method for determining a polishing recipe based on area response data acquired by changing a pressure for each area in a top ring, the method comprising the steps of:
determining a polishing recipe by simulation by a simulation unit based on new area response data;
comparing an actual polishing result obtained by actually polishing using the polishing recipe with a simulation polishing result obtained by simulation using the polishing recipe by an acceptance evaluation unit to evaluate an acceptance of the actual polishing result;
estimating and outputting, when the acceptance evaluation unit evaluates non-acceptance, corrected area response data by a response data correction unit having a third learned model machine-learning relationship between a past actual polishing result, a simulation polishing result, area response data used for determination of a polishing recipe at that time, and corrected area response data using an actual polishing result evaluated as non-acceptance, a simulation polishing result, and area response data used for the determination of a polishing recipe at that time as an input; and
again determining a polishing recipe by simulation by the simulation unit based on the corrected area response data estimated by the response data correction unit.

13. A polishing recipe determination program causing a computer to execute a process for determining a polishing recipe based on area response data acquired by changing a pressure for each area in a top ring, the program causing the computer to execute the steps of:
estimating and outputting presence or absence of an irregularity by an irregularity-presence-or-absence estimation unit having a first learned model machine-learning relationship between past area response data and whether an irregularity is present in the past area response data using new area response data as an input;
estimating and outputting, when the irregularity-presence-or-absence estimation unit estimates that an irregularity is present, area response data after removal of the irregularity by a screening unit having a second learned model machine-learning relationship between past area response data with an irregularity and area response data after removal of an irregularity using area response data estimated that an irregularity is present as an input; and
determining a polishing recipe by simulation by the simulation unit based on area response data estimated that no irregularity is present by the irregularity-presence-or-absence estimation unit, or area response data after the removal of the irregularity estimated by a screening unit.

14. The polishing recipe determination program according to claim 13, wherein
the program further causes the computer to execute the steps of:
comparing an actual polishing result obtained by actually polishing using the polishing recipe with a simulation polishing result obtained by simulation using the polishing recipe by an acceptance evaluation unit to evaluate an acceptance of the actual polishing result;
estimating and outputting, when the acceptance evaluation unit evaluates non-acceptance, corrected area response data by a response data correction unit having a third learned model machine-learning relationship between a past actual polishing result, a simulation polishing result, area response data used for determination of a polishing recipe at that time, and corrected area response data using an actual polishing result evaluated as non-acceptance, a simulation polishing result, and area response data used for the determination of a polishing recipe at that time as an input; and
again determining a polishing recipe by simulation by the simulation unit based on the corrected area response data estimated by the response data correction unit.

15. A polishing recipe determination program causing a computer to execute a process for determining a polishing recipe based on area response data acquired by changing a pressure for each area in a top ring, the program causing the computer to execute the steps of:
determining a polishing recipe by simulation by a simulation unit based on new area response data;
comparing an actual polishing result obtained by actually polishing using the polishing recipe with a simulation polishing result obtained by simulation using the polishing recipe by an acceptance evaluation unit to evaluate an acceptance of the actual polishing result;
estimating and outputting, when the acceptance evaluation unit evaluates non-acceptance, corrected area response data by a response data correction unit having a third learned model machine-learning relationship between a past actual polishing result, a simulation polishing result, area response data used for determination of a polishing recipe at that time, and corrected area response data using an actual polishing result evaluated as non-acceptance, a simulation polishing result, and area response data used for the determination of a polishing recipe at that time as an input; and
again determining a polishing recipe by simulation by the simulation unit based on the corrected area response data estimated by the response data correction unit.

16. A computer-readable recording medium recording a program causing a computer to execute a process for determining a polishing recipe based on area response data acquired by changing a pressure for each area in a top ring, the program causing the computer to execute the steps of:
estimating and outputting presence or absence of an irregularity by an irregularity-presence-or-absence estimation unit having a first learned model machine-learning relationship between past area response data and whether an irregularity is present in the past area response data using new area response data as an input;
estimating and outputting, when the irregularity-presence-or-absence estimation unit estimates that an irregularity is present, area response data after removal of the irregularity by a screening unit having a second learned model machine-learning relationship between past area response data with an irregularity and area response data after removal of an irregularity using area response data estimated that an irregularity is present as an input; and
determining a polishing recipe by simulation by the simulation unit based on area response data estimated that no irregularity is present by the irregularity-presence-or-absence estimation unit, or area response data after the removal of the irregularity estimated by a screening unit.

17. The computer-readable recording medium recording a program according to claim 16, wherein
the program further causes the computer to execute the steps of:
comparing an actual polishing result obtained by actually polishing using the polishing recipe with a simulation polishing result obtained by simulation using the polishing recipe by an acceptance evaluation unit to evaluate an acceptance of the actual polishing result;
estimating and outputting, when the acceptance evaluation unit evaluates non-acceptance, corrected area response data by a response data correction unit having a third learned model machine-learning relationship between a past actual polishing result, a simulation polishing result, area response data used for determination of a polishing recipe at that time, and corrected area response data using an actual polishing result evaluated as non-acceptance, a simulation polishing result, and area response data used for the determination of a polishing recipe at that time as an input; and
again determining a polishing recipe by simulation by the simulation unit based on the corrected area response data estimated by the response data correction unit.

18. A computer-readable recording medium recording a program causing a computer to execute a process for determining a polishing recipe based on area response data acquired by changing a pressure for each area in a top ring, the program causing the computer to execute the steps of:
determining a polishing recipe by simulation by a simulation unit based on new area response data;
comparing an actual polishing result obtained by actually polishing using the polishing recipe with a simulation polishing result obtained by simulation using the polishing recipe by an acceptance evaluation unit to evaluate an acceptance of the actual polishing result;
estimating and outputting, when the acceptance evaluation unit evaluates non-acceptance, corrected area response data by a response data correction unit having a third learned model machine-learning relationship between a past actual polishing result, a simulation polishing result, area response data used for determination of a polishing recipe at that time, and corrected area response data using an actual polishing result evaluated as non-acceptance, a simulation polishing result, and area response data used for the determination of a polishing recipe at that time as an input; and
again determining a polishing recipe by simulation by the simulation unit based on the corrected area response data estimated by the response data correction unit.
